(19) United States
(12) Patent Application Publication
(10) Pub. No.: US 2020/0225731 A1
(43) Pub. Date: Jul. 16, 2020

(54) MAINTAINING STATE INTEGRITY OF MEMORY SYSTEMS ACROSS POWER STATE TRANSITIONS

(71) Applicant: NVIDIA Corp., Santa Clara, CA (US)

(72) Inventor: Sachin Idgunji, San Jose, CA (US)

(21) Appl. No.: 15/929,088

(22) Filed: Jan. 11, 2019

(51) Int. Cl. G06F 1/3234; H03K 19/177; H03K 19/00; G11C 8/16

(52) U.S. Cl. CPC G06F 1/3275; G11C 8/16; H03K 19/0016; H03K 19/1776

(57) ABSTRACT

A periphery circuit of a memory array is formed in a first power domain, and an output latch of the periphery circuit domain is formed in a second power domain different than the first power domain. During power state transitions the state integrity of the output latch is maintained.

### BACKGROUND

Power gating to enable low power modes such as standby power mode are well known techniques in modern integrated circuit design. For volatile memory devices such as SRAM memory arrays, techniques exist to power gate the entire memory array and to power gate the memory array periphery and maintain the memory array in a leakage mode. These techniques, such as clock gating the memory array periphery, enable power gating or data retention state. In a clock gated state the clock is disengaged from the circuits in the memory array periphery, so that there is no operational activity in the periphery circuit domain. In a clock gated state sequential elements in the memory array periphery retain their state.

However, these techniques introduce latency in the transition from the data retention state to the operational power state. There is thus a need for improved power management between power states in complex circuits, especially in regards to volatile memory devices.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a volatile memory device 100 in accordance with one embodiment.

FIG. 2 illustrates a volatile memory device 100 in accordance with one embodiment.

FIG. 3 illustrates a volatile memory device output stage 300 in accordance with one embodiment.

FIG. 4 illustrates a volatile memory device output stage 300 in accordance with another embodiment.

FIG. 5 illustrates a computing system 500 within which the circuits and methods introduced herein may be embodied.

### DETAILED DESCRIPTION

“Power domain” refers to refers to a sub-area of an integrated circuit having a power source independently supplied and optionally controlled relative to other sub-areas of the integrated circuit.

“Periphery circuit domain” refers to the power domain of a memory array periphery.

“Memory array periphery” refers to circuitry utilized for reading and writing to a memory array.

“Low power state” refers to a power state in which circuitry is disabled from receiving operational mode power.

“Operational power state” refers to the power state in which circuitry operates in its uninhibited operational mode. In the operational power state of circuitry consumes more power than when placed in a low power state.

“Power manager” refers to circuitry that manages the transition of circuits between power states.

“Power state control logic” refers to a power manager.

“Standby mode” refers to a low power state in which circuitry maintains state (stored settings) but is not in an operational mode.

“Standby power” refers to the power source for circuits in standby mode.

In conventional memory systems utilizing memory array periphery power gating, output latches and other sequential elements (either non-pipelined or pipelined) lose state integrity when the memory array periphery is placed into a low power mode and then restored to an operational mode. The resumption of operational mode from the standby mode cannot mimic the benefits of a data retention state that resumes from clock gating (see Background).

The circuits and techniques disclosed herein utilize sequential elements in the memory array periphery that are controlled in a manner that addresses the limitations of the prior art. A number of possible embodiments include:

1) The output latches and other sequential elements are powered from a non-power-gated power supply with a power gate applied to the remainder of the memory array periphery.

2) The output latches in the memory array periphery are associated with one or more shadow register such as a balloon latch (e.g., designed from HVT cells), and the output latch(s) are power gated (e.g., included in the power-gated memory array periphery. The balloon latch retains state when the memory array periphery is placed into a low power state such as standby mode. When the operational power state is restored from standby mode, the retained state in the balloon latch is transferred to the output latch.

3) The output latches are powered from the same power supply that powers the memory array. The state of the last read access to the memory array prior to transitioning the memory array to the low power state is retained in the output latches. The output latches are powered by the same power rail, either directly or indirectly, as the power rail that powers the memory array.

With any of these three mechanisms, the sequential elements in the output path of the volatile memory device resume from the standby mode to the operational mode with their state integrity preserved, thereby appearing as if exiting from a clock gated state. This allows for a finer resolution of circuit power management.

The state of the input latches to the memory array (address, command, data) does not need to be retained and thus the input latches may be power gated (and thus included in the power-gated memory array periphery).

Conventional approaches utilize power gates to the memory array periphery, but do not retain the state of the output latches during transitions to and from a low power state. The disclosed embodiments maintain the state integrity of the output latches across power state transitions, at the cost of some small additional energy leakage. If balloon latches are utilized at the expense of slightly larger circuit size, leakage may be reduced even further, because balloon latches may be designed using HVT cells. The balloon latches preserve state and typically would not be used (have their power switched off) in the operational power state of the memory array.

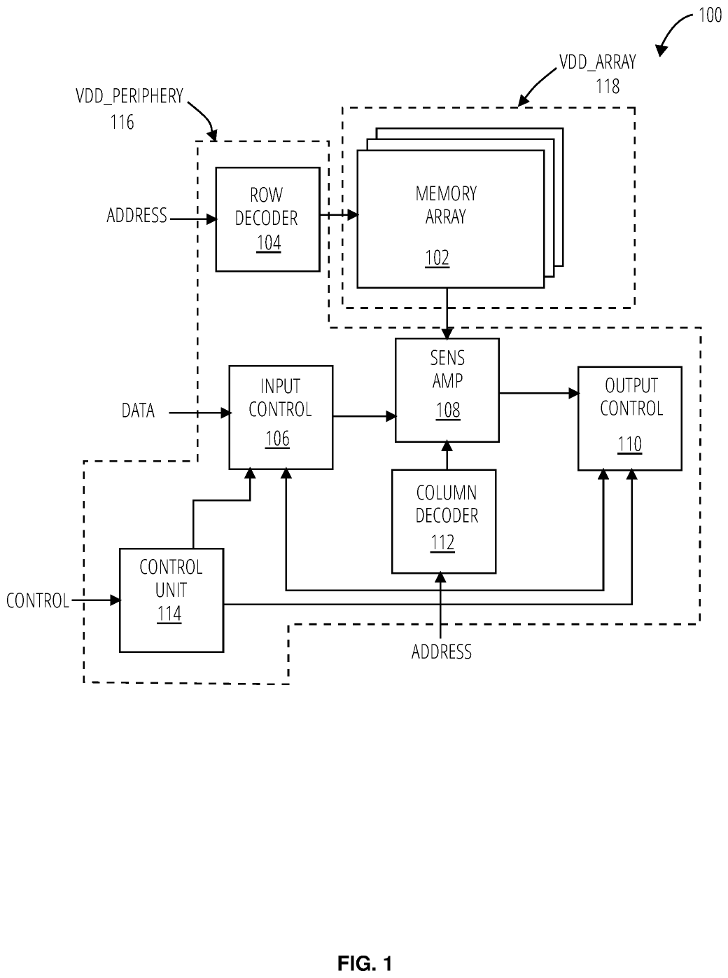

Referring to the volatile memory device 100 embodiment of FIG. 1, two power gated circuit domains are utilized in a volatile memory device for use in low power modes. The memory array, which is placed into a data retention state in standby mode, is in a separate memory array power domain 118 (VDD_ARRAY) from the periphery power domain 116 (VDD_PERIPHERY).

The volatile memory device 100 comprises a memory array 102, a row decoder 104, an input data control 106, a sense amplifier 108, an output data control 110, a column decoder 112, and a control unit 114.

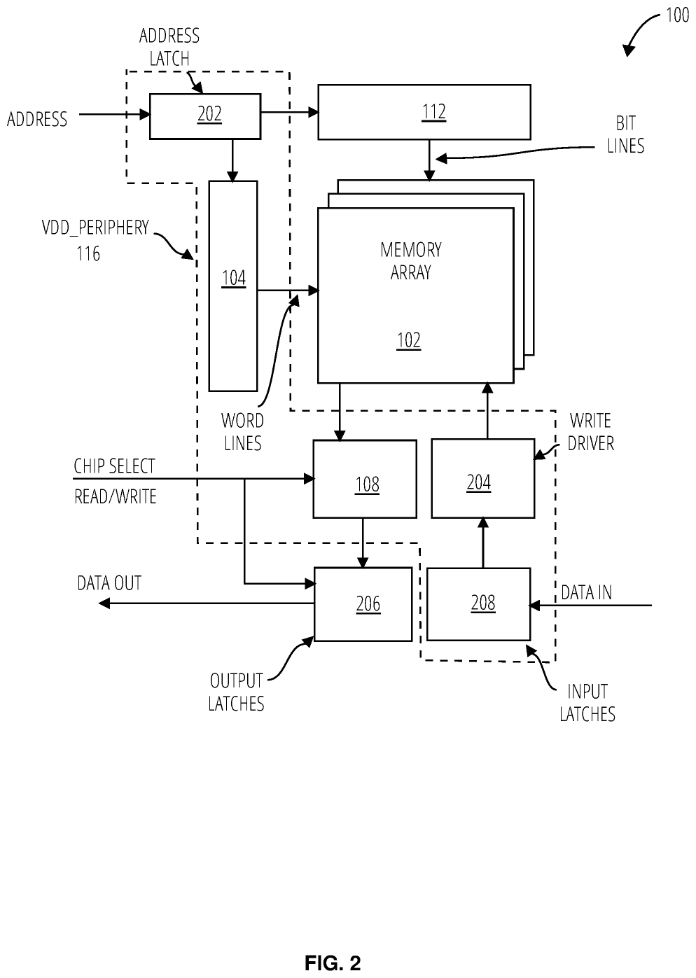

Referring to the volatile memory device 100 of FIG. 2, in addition to components introduced in conjunction with FIG. 2, the volatile memory device 100 comprises an address latch 202, a write driver 204, output latches 206, and input latches 208. The function and structure of these components is well known in the art of memory circuit design.

The output latches 206 process the output of the memory array 102. When power gates of the periphery power domain 116 are switched off to enter a low power state (e.g., a standby mode), the state of the output latches 206 would be lost in conventional approaches, and when the power gates of the periphery power domain 116 are switched back on to transition back to the operational power state, the output latches 206 may re-activate in an arbitrary state, thus losing state integrity.

However, as illustrated the output latches 206 are not power gated in the periphery power domain 116, and thus retain state across power state transitions.

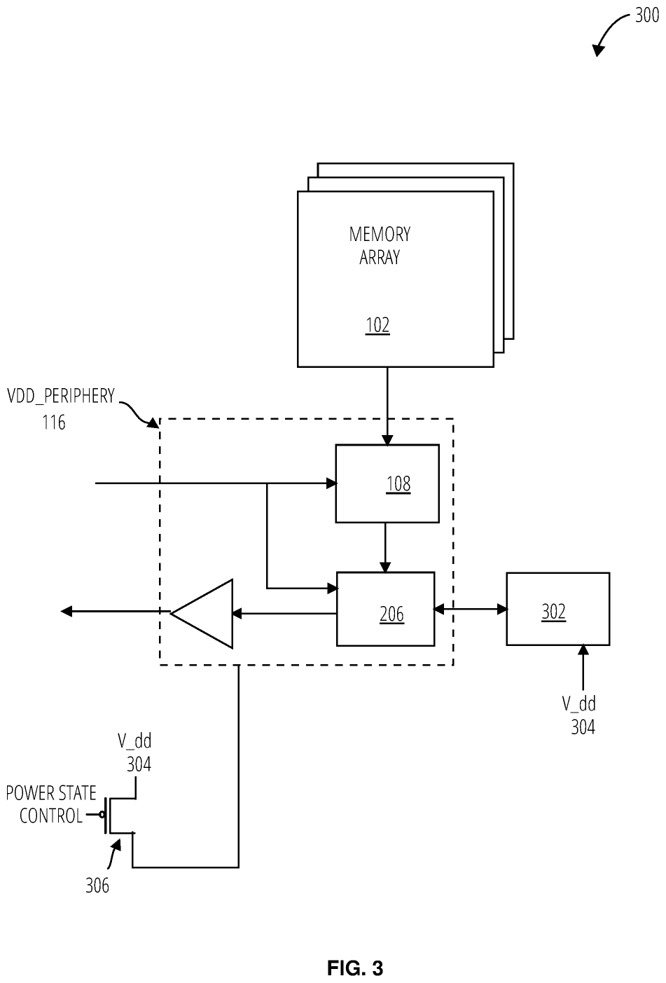

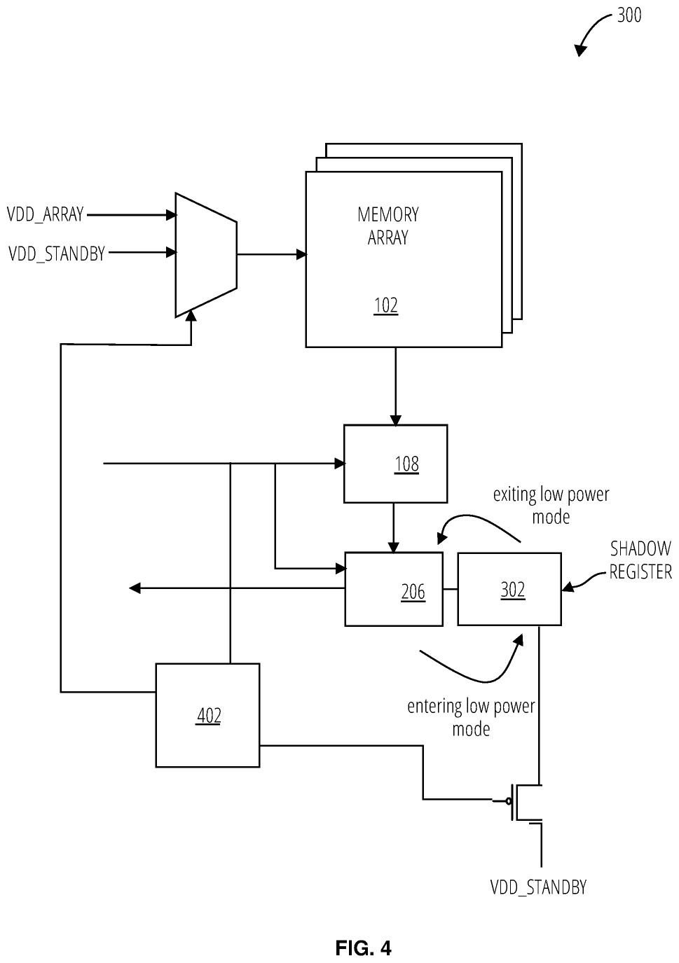

FIG. 4 and FIG. 3 illustrate a low-latency volatile memory device output stage 300 to address the loss of state integrity of the output latches 206 when transitioning between a low power state and an operational power state. In addition to the components introduced in conjunction with FIG. 1 and FIG. 2, the volatile memory device output stage 300 comprises a shadow register 302.

Most of the output stage components are power gated in the periphery power domain 116, including the output latches 206, but the shadow register 302 is not power gated, so that its state is retained during transitions from operational power state to low power state and vice versa.

In some embodiments, as shown in FIG. 2, the one or more output latches 206 may be formed outside the periphery power domain 116 and may thus retain power and state when the periphery power domain 116 is placed into the low power state via operation of a power gate. The output latches 206 may in some cases be implemented using balloon latches. The output latches 206 may in some cases be switched to operate in the standby mode power domain during transition to the low power state (see the related description below for a shadow register implementation).

In some embodiments, as shown in FIG. 3, the shadow register 302 may be supplied from a non-power-gated power supply 304, e.g., the same power supply powering the periphery power domain 116 in the operational mode via a power gate 306.

In some embodiments, as shown in FIG. 4, while transitioning to the low power state, the power state control logic 402 may cause the shadow register 302 to receive power from the standby mode power rail that powers the memory array 102 in standby mode. While transitioning to the operational power state the power state control logic 402 may cause the shadow register 302 to receive no power, and thus consume no power. The power state control logic 402 (which may be part of the output data control 110) may operate to move the data from the output latches 206 to the shadow register 302 during the transition from the operational power state to the low power state, and to move data from the shadow register 302 to the output latches 206 when returning from the low power state to the operational power state. The shadow register 302 may be implemented using a balloon latch in some embodiments.

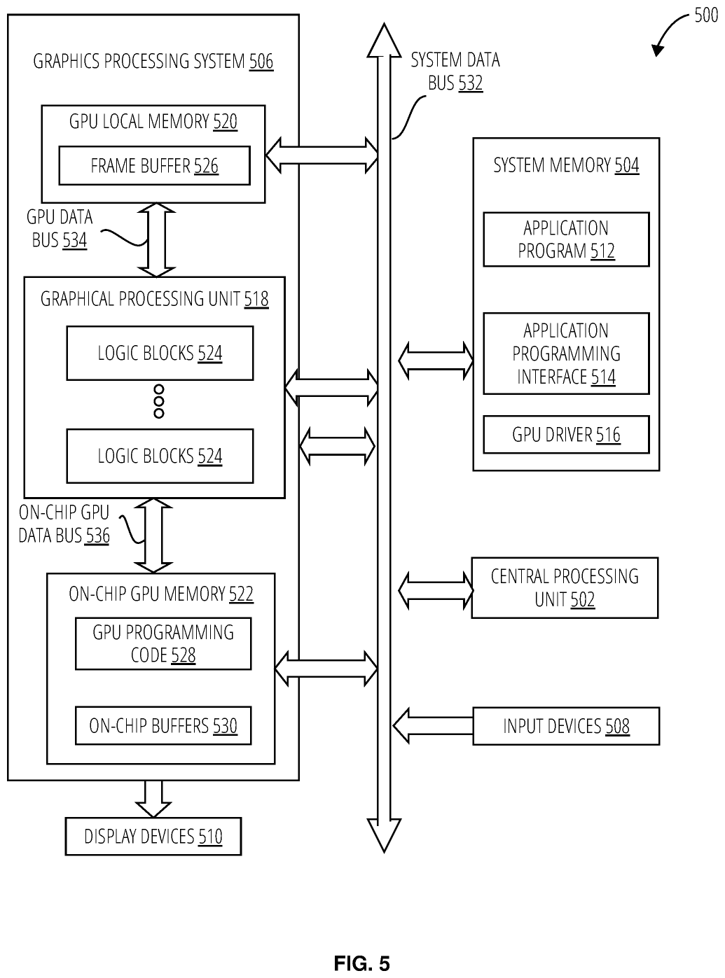

FIG. 5 is a block diagram of one embodiment of a computing system 500 in which one or more aspects of the disclosure may be implemented. The computing system 500 includes a system data bus 532, a CPU 502, input devices 508, a system memory 504, a graphics processing system 506, and display devices 510. In alternate embodiments, the CPU 502, portions of the graphics processing system 506, the system data bus 532, or any combination thereof, may be integrated into a single processing unit. Further, the functionality of the graphics processing system 506 may be included in a chipset or in some other type of special or general purpose processing unit or co-processor, such as a system-on-a-chip (SOC).

As shown, the system data bus 532 connects the CPU 502, the input devices 508, the system memory 504, and the graphics processing system 506. In alternate embodiments, the system memory 504 may connect directly to the CPU 502. The CPU 502 receives user input from the input devices 508, executes programming instructions stored in the system memory 504, operates on data stored in the system memory 504 to perform computational tasks. The system memory 504 typically includes dynamic random access memory (DRAM) employed to store programming instructions and data. The graphics processing system 506 receives instructions transmitted by the CPU 502 and processes the instructions, for example to implement aspects of the disclosed embodiments, and/or to render and display graphics (e.g., images, tiles, video) on the display devices 510.

As also shown, the system memory 504 includes an application program 512, an API 514 (application programming interface), and a graphics processing unit driver 516 (GPU driver). The application program 512 generates calls to the API 514 to produce a desired set of computational results. For example, the application program 512 may transmit programs or functions thereof to the API 514 for processing within the graphics processing unit driver 516.

The graphics processing system 506 includes a GPU 518 (graphics processing unit), an on-chip GPU memory 522, an on-chip GPU data bus 536, a GPU local memory 520, and a GPU data bus 534. The GPU 518 is configured to communicate with the on-chip GPU memory 522 via the on-chip GPU data bus 536 and with the GPU local memory 520 via the GPU data bus 534. The GPU 518 may receive instructions transmitted by the CPU 502, process the instructions, and store results in the GPU local memory 520. Subsequently, the GPU 518 may display certain graphics stored in the GPU local memory 520 on the display devices 510. The GPU 518 includes one or more logic blocks 524. The logic blocks 524 may implement data processing functionality such as graphics processing and manipulation, or more general programming algorithms.

The invention may be utilized for example with one or more of the on-chip GPU memory 522, GPU local memory 520, and system memory 504. The GPU 518 may be provided with any amount of on-chip GPU memory 522 and GPU local memory 520, including none, and may employ on-chip GPU memory 522, GPU local memory 520, and system memory 504 in any combination for memory operations.

The on-chip GPU memory 522 is configured to include GPU programming 528 and on-Chip Buffers 530. The GPU programming 528 may be transmitted from the graphics processing unit driver 516 to the on-chip GPU memory 522 via the system data bus 532. The GPU programming 528 may include the logic blocks 524.

The GPU local memory 520 typically includes less expensive off-chip dynamic random access memory (DRAM) and is also employed to store data and programming employed by the GPU 518. As shown, the GPU local memory 520 includes a frame buffer 526. The frame buffer 526 may for example store data for example an image, e.g., a graphics surface, that may be employed to drive the display devices 510. The frame buffer 526 may include more than one surface so that the GPU 518 can render one surface while a second surface is employed to drive the display devices 510.

The display devices 510 are one or more output devices capable of emitting a visual image corresponding to an input data signal. For example, a display device may be built using a liquid crystal display, or any other suitable display system. The input data signals to the display devices 510 are typically generated by scanning out the contents of one or more frames of image data that is stored in the frame buffer 526.

Terms used herein should be accorded their ordinary meaning in the relevant arts, or the meaning indicated by their use in context, but if an express definition is provided, that meaning controls.

“Circuitry” refers to electrical circuitry having at least one discrete electrical circuit, electrical circuitry having at least one integrated circuit, electrical circuitry having at least one application specific integrated circuit, circuitry forming a general purpose computing device configured by a computer program (e.g., a general purpose computer configured by a computer program which at least partially carries out processes or devices described herein, or a microprocessor configured by a computer program which at least partially carries out processes or devices described herein), circuitry forming a memory device (e.g., forms of random access memory), or circuitry forming a communications device (e.g., a modem, communications switch, or optical-electrical equipment).

“Firmware” refers to software logic embodied as processor-executable instructions stored in read-only memories or media.

“Hardware” refers to logic embodied as analog or digital circuitry.

“Logic” refers to machine memory circuits, non transitory machine readable media, and/or circuitry which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter).

Certain aspects (e.g., control) may be implemented by logic distributed over one or more discrete device, according to the requirements of the implementation.

“Software” refers to logic implemented as processor-executable instructions in a machine memory (e.g. read/write volatile or nonvolatile memory or media).

Herein, references to “one embodiment” or “an embodiment” do not necessarily refer to the same embodiment, although they may. Unless the context clearly requires otherwise, throughout the description and the claims, the words “comprise,” “comprising,” and the like are to be construed in an inclusive sense as opposed to an exclusive or exhaustive sense; that is to say, in the sense of “including, but not limited to.” Words using the singular or plural number also include the plural or singular number respectively, unless expressly limited to a single one or multiple ones. Additionally, the words “herein,” “above,” “below” and words of similar import, when used in this application, refer to this application as a whole and not to any particular portions of this application. When the claims use the word “or” in reference to a list of two or more items, that word covers all of the following interpretations of the word: any of the items in the list, all of the items in the list and any combination of the items in the list, unless expressly limited to one or the other. Any terms not expressly defined herein have their conventional meaning as commonly understood by those having skill in the relevant art(s).

Various logic functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on.

What is claimed is:

1. A memory system comprising:
a memory array;
a power-gated periphery circuit domain of the memory array; and
an output latch of the periphery circuit domain coupled to a shadow register that is not power-gated.

2. The memory system of claim 1, further comprising:
power state control logic to transfer a state of the output latch to the shadow register during a transition of the periphery circuit domain from an operational power state to a low power state.

3. The memory system of claim 2, further comprising:
the power state control logic to transfer a state of the shadow register to the output latch upon a transition of the periphery circuit domain from the low power state to the operational power state.

4. The memory system of claim 1, the shadow register comprising a balloon latch.

5. The memory system of claim 4, the power state control logic switching the balloon latch to receive power from a standby mode power source of the memory array during a transition of the memory array to a standby mode.

6. The memory system of claim 5, the power state control logic switching off power to the balloon latch in the operational power state.

7. A graphics processing unit comprising:
a memory array;
a periphery circuit of the memory array in a first power domain, the periphery circuit comprising addressing circuits for the memory array, read and write drivers for the memory array, and input latches for the memory array; and
an output latch of the periphery circuit domain in a second power domain different than the first power domain.

8. The memory system of claim 7, the output latch comprising a balloon latch.

9. The memory system of claim 7, the power state control logic configured to switch the output latch to receive power from a standby mode power source of the memory array when transitioning the memory array to the standby mode.

10. The memory system of claim 9, the power state control logic configured to switch the output latch to the operational power state upon transitioning the memory array from the standby mode to the operational mode.

11. A method of operating a memory system, the method comprising:
transferring a state of an output latch in a first power domain of a memory array to a shadow register in a second power domain during a transition of a periphery circuit domain of the memory array from an operational power state to a low power state; and
transferring a state of the shadow register to the output latch upon a transition of the periphery circuit domain from the low power state to the operational power state.

12. The method of claim 11, wherein the shadow register is a balloon latch.

13. The method of claim 11, the first power domain a periphery circuit domain of the memory array.

14. The method of claim 12, the second power domain a standby power domain of the memory array.

15. The method of claim 12, the memory array an on-chip memory array of a graphics processing unit or system-on-a-chip.
